(19) United States
(12) Patent Application Publication
(10) Pub. No.: US 2022/0206082 A1
(43) Pub. Date: Jun. 30, 2022

(54) MODEL-BASED METHOD AND SYSTEM FOR DIAGNOSING OPEN-CIRCUIT FAULT OF POWER TRANSISTOR OF THREE-PHASE CONVERTER

(71) Applicant: WUHAN UNIVERSITY, HUBEI (CN)

(72) Inventors: Yigang HE, Hubei (CN); Chunsong Sui, HUBEI (CN); Hui ZHANG, Hubei (CN)

(73) Assignee: WUHAN UNIVERSITY, HUBEI (CN)

(21) Appl. No.: 17/523,909

(22) Filed: Nov. 11, 2021

(30) Foreign Application Priority Data
Dec. 29, 2020 (CN) 202011591686.8

(51) Int. Cl. G01R 31/54; H02M 7/219

(52) U.S. Cl. CPC G01R 31/54; H02M 7/219

(57) ABSTRACT

A model-based method and system for diagnosing an open-circuit fault of a power transistor of a three-phase converter are provided, which belong to the technical field of fault diagnosis of power electronic equipment and can implement fast and accurate diagnosis of the open-circuit fault of the power transistor of the three-phase converter without adding an additional hardware. The fault diagnosis method of the disclosure only needs current and voltage sampling signals and drive signals that already exist in a control system of the converter and has the advantage of simple implementation. A cycle accumulated value of a difference between a sampling current and an estimated current after the power transistor of the converter has the open-circuit fault is used as a diagnostic variable, which can quickly and accurately complete diagnosis of a faulty power transistor and has relatively strong practicability.

### CROSS-REFERENCE TO RELATED APPLICATION

This application claims the priority benefit of China application serial no. 202011591686.8, filed on Dec. 29, 2020. The entirety of the above-mentioned patent application is hereby incorporated by reference herein and made a part of this specification.

### BACKGROUND

### Technical Field

The disclosure relates to the technical field of fault diagnosis of power electronic equipment, and more specifically relates to a model-based method and system for diagnosing an open-circuit fault of a power transistor of a three-phase two-level converter.

### Description of Related Art

The three-phase converter has been widely researched and applied in application scenarios such as micronet, energy storage, and uninterruptible power supply. In the application scenarios, the safe and stable operation of the converter is very important. According to industrial surveys, the power transistor is one of the most vulnerable elements. The open-circuit fault of the power transistor of the converter causes current distortion and fluctuations in the direct current voltage, and even shutdown of the equipment when not handled for a long time. Therefore, the fast fault diagnosis of the power transistor that has the open-circuit fault is of great significance for improving the reliability of the converter.

At present, the existing domestic and foreign fault diagnosis technologies for the three-phase converter may be roughly divided into the current signal-based fault diagnosis methods, the voltage signal-based fault diagnosis method, the model-based fault diagnosis method, and the artificial intelligence-based fault diagnosis method. The current signal-based fault diagnosis method implements the fault diagnosis according to the difference between the alternating current side current waveform after the fault and the current waveform (sine wave) under normal conditions. Therefore, such algorithm is usually simpler, but it is inevitable that the influence of the power of the load is greater, and the diagnosis time is usually longer. The voltage signal-based fault diagnosis method obtains a voltage signal sensitive to the state of the power transistor through an additional hardware or a voltage sensor. Therefore, the diagnosis speed is faster, but the additional hardware increases the complexity and cost of the design. The artificial intelligence-based fault diagnosis algorithm implements the diagnosis of the faulty power transistor by adopting an intelligent algorithm based on the analysis of the historical voltage and current sampling signals of the converter. The calculation is large and difficult to be implemented in the original control system of the converter. The model-based fault diagnosis method implements the diagnosis of the faulty power transistor by calculating the voltage or current value according to a model, and comparing with a corresponding signal obtained by sampling. The calculation amount is less than the artificial intelligence-based fault diagnosis method, and the diagnosis speed is faster, but a more accurate mathematical model is usually required.

It can be seen that without adding the additional hardware, the implementation of a fast, accurate, and simple open-circuit fault diagnosis of a power transistor is still an urgent issue to be solved.

### SUMMARY

In view of the above defects or improvement requirements of the prior art, the disclosure proposes a model-based method and system for diagnosing an open-circuit fault of a power transistor of a three-phase converter, which can implement fast and accurate diagnosis of the open-circuit fault of the power transistor of the three-phase converter without adding an additional hardware.

In order to achieve the above objective, according to one aspect of the disclosure, the model-based method for diagnosing the open-circuit fault of the power transistor of the three-phase converter is provided, which includes the following steps.

In Step (1), relevant signals for diagnosis are obtained from a control system of a converter. The relevant signals include an alternating current side three-phase current sampling signal i_{X}[k] of the converter, an alternating current side three-phase voltage sampling signal e_{X}[k], where the subscript X (=A, B, or C) represents a present phase sequence and k represents a sampling time, a direct current side voltage sampling signal U_{dc}[k], and drive signals s₁[k] to s₆[k] output by the control system.

In Step (2), an estimated change value Δi_{EX}[k] of a three-phase current during each switching cycle Tₛ is calculated through the alternating current side three-phase voltage sampling signal e_{X}[k], the direct current side voltage sampling signal U_{dc}[k], and the drive signals s₁[k] to s₆[k] output by the control system according to a converter model.

In Step (3), a residual δi_{X}[k] of the three-phase current during each switching cycle Tₛ is calculated according to a change value Δi_{X}[k] of a three-phase current sampling signal during each switching cycle Tₛ and the estimated change value Δi_{EX}[k] of a three-phase current.

In Step (4), an accumulated value δi_{TX}[k] of a residual of the three-phase current during one basic cycle T₀ is calculated according to the residual δi_{X}[k] of the three-phase current during each switching cycle Tₛ.

In Step (5), the power transistor that has the open-circuit fault is determined according to a comparison between the accumulated value δi_{TX}[k] of the residual of the three-phase current during each basic cycle T₀ and a threshold Th.

In some optional embodiments, in Step (2), the converter model refers to a mathematical model derived from Kirchhoff's voltage law and Kirchhoff's current law in combination with a topology of the converter.

In some optional implementations, in Step (2), the switching cycle Tₛ is a reciprocal of a switching frequency fₛ, and the switching frequency fₛ refers to the number of times of switching the power transistor per second.

In some optional implementations, in Step (2), the estimated change value Δi_{EX}[k] of the three-phase current during each switching cycle Tₛ may be implemented through various forms such as calculations by a state observer and a mixed logic dynamic model according to the converter model.

In some optional implementations, in Step (3), the change value Δi_{X}[k] of the three-phase current sampling signal during each switching cycle Tₛ refers to a difference between three-phase current sampling signal i_{X}[k] corresponding to a start and an end of each switching cycle Tₛ, that is, Δi_{X}[k]=i_{X}[k]−i_{X}[k−1].

In some optional implementations, in Step (3), the residual δi_{X}[k] of the three-phase current during each switching cycle Tₛ refers to a difference between the change value Δi_{X}[k] of the three-phase current sampling signal during each switching cycle Tₛ and the estimated change value Δi_{EX}[k] of the three-phase current during each switching cycle Tₛ, that is, δi_{X}[k]=Δi_{X}[k]−Δi_{EX}[k].

In some optional embodiments, in Step (4), the basic cycle T₀ refers to a reciprocal of a three-phase voltage frequency f₀, and the three-phase voltage frequency f₀ is 50 Hz.

In some optional implementations, in Step (4), the accumulated value δi_{TX}[k] of the residual of the three-phase current during the basic cycle T₀ is a sum of the residual δi_{X}[k] of the three-phase current during all the switching cycles during the previous basic cycle T₀ of a current time, that is, δi_{TX}[k]=δi_{X}[k−T₀/Tₛ+1]+δi_{X}[k−T₀/Tₛ+2]+ . . . +δi_{X}[k−1]+δi_{X}[k].

In some optional implementations, in Step (5), the threshold Th refers to a threshold value set to prevent misdiagnosis, that is, when the accumulated value δi_{TX}[k] of the residual of the three-phase current during the basic cycle T₀ exceeds the threshold value, it is determined that the power transistor has the open-circuit fault. The threshold needs to be selected in combination with requirements for diagnosis speed and reliability.

In some optional implementations, in Step (5), for different faults of the power transistor, the accumulated value δi_{TX}[k] of the residual of the three-phase current during the basic cycle T₀ is different, so that the faulty power transistor can be located through the accumulated value δi_{TX}[k].

In some optional implementations, in Step (5), when a maximum value of the accumulated value δi_{TX}[k] of the residual of the three-phase current during the basic cycle T₀ is greater than the set threshold Th, it is determined that a fault has occurred.

Based on the above steps, the disclosure may basically complete the diagnosis of the faulty power transistor within ten switching cycles (for example, 1 ms when the switching frequency fₛ is 10 kHz) after the power transistor has the open-circuit fault.

According to another aspect of the disclosure, a model-based system for diagnosing an open-circuit fault of a power transistor of a three-phase converter is provided, which includes the following.

A diagnosis signal obtaining module is configured to obtain relevant signals for diagnosis from a control system of a converter. The relevant signals include an alternating current side three-phase current sampling signal i_{X}[k] of the converter, an alternating current side three-phase voltage sampling signal e_{X}[k], where the subscript X (=A, B, or C) represents a present phase sequence and k represents a sampling time, a direct current side voltage sampling signal U_{dc}[k], and drive signals s₁[k] to s₆[k] output by the control system.

A first calculation module is configured to calculate an estimated change value Δi_{EX}[k] of a three-phase current during each switching cycle Tₛ through the alternating current side three-phase voltage sampling signal e_{X}[k], the direct current side voltage sampling signal U_{dc}[k], and the drive signals s₁[k] to s₆[k] output by the control system according to a converter model.

A second calculation module is configured to calculate a residual δi_{X}[k] of the three-phase current during each switching cycle according to a change value Δi_{X}[k] of a three-phase current sampling signal during each switching cycle Tₛ and the estimated change value Δi_{EX}[k] of the three-phase current.

A third calculation module is configured to calculate an accumulated value δi_{TX}[k] of a residual of the three-phase current during one basic cycle T₀ according to the residual δi_{X}[k] of the three-phase current during each switching cycle.

A fault diagnosis module is configured to determine the power transistor that has the open-circuit fault according to a comparison between the accumulated value δi_{TX}[k] of the residual of the three-phase current during each basic cycle T₀ and a threshold Th.

According to another aspect of the disclosure, a computer-readable storage medium stored with a computer program is provided. When the computer program is executed by a processor, the steps of the method are implemented.

Generally speaking, compared with the prior art, the above technical solutions conceived by the disclosure can achieve the following beneficial effects.

According to the converter model, the three-phase alternating current is calculated through the voltage sampling signal and the drive signals that already exist in the control system of the converter, through the residual of the three-phase current and the difference between the alternating current value obtained by sampling and the alternating current value obtained by calculation, the cycle accumulated value of the difference between the sampling current and the estimated current after the power transistor of the converter has the open-circuit fault is used as a diagnostic variable, which can quickly and accurately complete diagnosis of a faulty power transistor and has relatively strong practicability.

### BRIEF DESCRIPTION OF THE DRAWINGS

FIG. 1 is a schematic diagram of a main circuit and a control system of a three-phase two-level converter (rectifier mode) system according to an embodiment of the disclosure,

FIG. 2 is a schematic flowchart of a model-based method for diagnosing an open-circuit fault of a power transistor according to an embodiment of the disclosure.

FIG. 3 is a schematic diagram of an experimental result of adopting a method of the disclosure after a power transistor has an open-circuit fault according to an embodiment of the disclosure.

### DETAILED DESCRIPTION OF DISCLOSED EMBODIMENTS

In order for the objectives, technical solutions, and advantages of the disclosure to be clearer, the following further describes the disclosure in detail with reference to the accompanying drawings and embodiments. It should be understood that the specific embodiments described here are only used to explain the disclosure, but not to limit the disclosure. In addition, the technical features involved in the various embodiments of the disclosure described below may be combined with each other as long as there is no conflict therebetween.

In the example of the disclosure, “first”, “second”, etc. are used to distinguish different objects and are not necessarily used to describe a specific order or sequence.

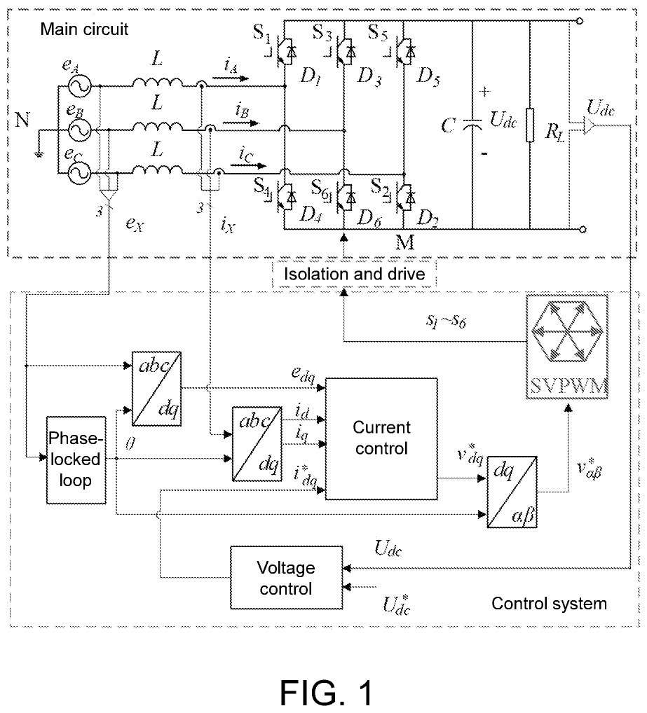

As shown in FIG. 1, a typical three-phase two-level converter includes six power transistors S₁ to S₆ and six matching diodes D₁ to D₆. The power transistors, the diodes, a filter inductor L, and a filter capacitor C jointly form a main circuit portion of the converter. A control system of the converter obtains a three-phase alternating current voltage e_{X}[k], a three-phase alternating current sampling signal i_{X}[k], and a direct current voltage value U_{dc}[k] of the main circuit through a sensor and an analog-to-digital converter (ADC), and calculates and outputs drive signals s₁ to s₆ to control the work of each power transistor.

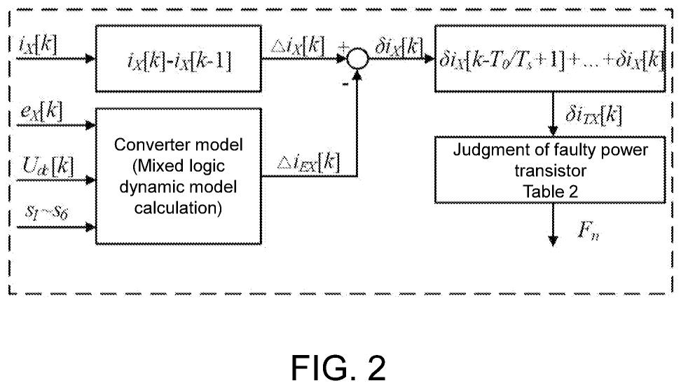

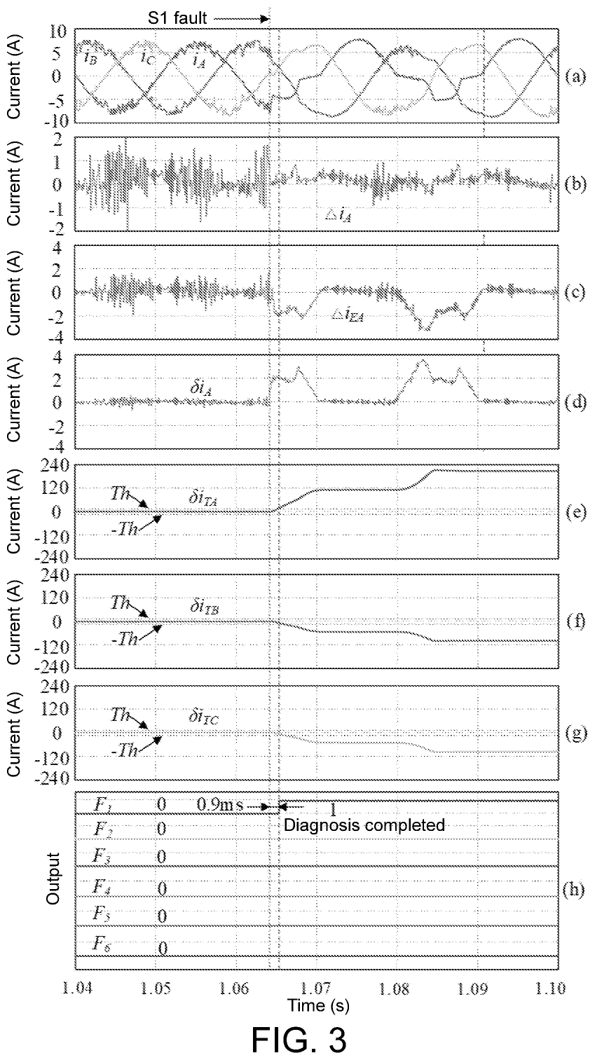

The schematic diagram of the diagnosis method of the disclosure is shown in FIG. 2. The experimental result of the embodiment is shown in FIG. 3, where (a) of FIG. 3 represents the three-phase current.

(1) Through three-phase current sampling signal i_{X}[k] corresponding to a start and an end of each switching cycle Tₛ, a change value Δi_{X}[k] of the three-phase current sampling signal during each switching cycle Tₛ is calculated, that is:

$$Δ {i}_{X} [ k ] = {i}_{X} [ k ] - {i}_{X} [ k - 1 ]$$

Taking A-phase as an example, a calculation result Δi_{A}[k] is shown in (b) of FIG. 3.

(2) It is necessary to combine a converter model, an estimated change value Δi_{EX}[k] of a three-phase current during each switching cycle Tₛ is calculated through an alternating current side three-phase current sampling signal i_{X}[k] of the converter, an alternating current side three-phase voltage sampling signal e_{X}[k], a direct current side voltage sampling signal U_{dc}[k], and drive signals s₁[k] to s₆[k] output by the control system.

In the converter, since the power transistors with the same phase cannot be turned on at the same time, a three-phase state S_{X} is commonly used to represent a working state of a three-phase power transistor. When S_{X}=1, it represents that upper bridge arm of an X-phase is turned on. When S_{X}=0, it represents that lower bridge arm of the X-phase is turned on. A relationship between the three-phase state S_{X} and the drive signals s₁ to s₆ and a direction p_{X}[k] of the three-phase current sampling signal i_{X}[k] is:

$$\{ \begin{matrix}{S}_{A} = {\overline{p}}_{A} \cdot {s}_{1} + {p}_{A} \cdot {s}_{4} \\ {S}_{B} = {\overline{p}}_{B} \cdot {s}_{3} + {p}_{B} \cdot {s}_{6} \\ {S}_{C} = {\overline{p}}_{C} \cdot {s}_{5} + {p}_{C} \cdot {s}_{2}\end{matrix}$$

where p_{X}[k] refers to the direction of the three-phase current sampling signal i_{X}[k], which is a 0-1 variable. When the three-phase current sampling signal i_{X}[k]>0, p_{X}[k]=1, p̅_{X}[k]=0, and conversely, p_{X}[k]=0, p̅_{X}[k]=1.

In addition, a basic vector Vₙ may also be used to represent the state of the three-phase power transistor, where n=0, 1, 2, 3, 4, 5, 6, 7, and the relationship with the three-phase state S_{X} is shown in Table 1.

TABLE 1

| Basic vector Vₙ | A-phase state S_{A} | B-phase state S_{B} | C-phase state S_{C} |
|---|---|---|---|
| V₀ | 0 | 0 | 0 |
| V₁ | 1 | 0 | 0 |
| V₂ | 1 | 1 | 0 |
| V₃ | 0 | 1 | 0 |
| V₄ | 0 | 1 | 1 |
| V₅ | 0 | 0 | 1 |
| V₆ | 1 | 0 | 1 |
| V₇ | 1 | 1 | 1 |

In the embodiment of the disclosure, the control system adopts double closed-loop control and seven-segment space vector pulse width modulation (SVPWM). Each different basic vector Vₙ (phase state S_{X}) corresponds to a respective action time tₙ.

In the embodiment of the disclosure, a mixed logic dynamic model is used to calculate the estimated change value Δi_{EX}[k] of the three-phase current during each switching cycle Tₛ. The mixed logic dynamic model regards a current change in a switching cycle as a piecewise function, and calculates the estimated change value Δi_{EX}[k] of the three-phase current during each switching cycle Tₛ through calculating a slope Kₙ^{X} of each segment and the corresponding time tₙ. In the three-phase two-level converter, the converter model may be obtained according to Kirchhoff s voltage law:

$$L \frac{{di}_{X}}{dt} + {Ri}_{X} = {e}_{X} - {U}_{d c} {S}_{X} - {U}_{MN}$$

According to Kirchhoff's voltage and current laws, it can be known that i_{A}[k]+i_{B}[k]+i_{C}[k]=0, e_{A}[k]+e_{B}[k]+e_{C}[k]=0, so it can be obtained that:

$${U}_{MN} = - \frac{{S}_{A} + {S}_{B} + {S}_{C}}{3} {U}_{d c}$$

According to the above equation, the calculation equation of the slope Kₙ^{X} may be obtained:

$$[ \begin{matrix}{K}_{n}^{A} \\ {K}_{n}^{B} \\ {K}_{n}^{C}\end{matrix} ] = \frac{d}{dt} [ \begin{matrix}{i}_{A} \\ {i}_{B} \\ {i}_{C}\end{matrix} ] = - \frac{R}{L} [ \begin{matrix}{i}_{A} \\ {i}_{B} \\ {i}_{C}\end{matrix} ] + \frac{1}{L} [ \begin{matrix}{e}_{A} \\ {e}_{B} \\ {e}_{C}\end{matrix} ] - \frac{{U}_{d c}}{3 L} [ \begin{matrix}2 & - 1 & - 1 \\ - 1 & 2 & - 1 \\ - 1 & - 1 & 2\end{matrix} ] [ \begin{matrix}{S}_{A} \\ {S}_{B} \\ {S}_{C}\end{matrix} ]$$

Therefore, the basic vector Vₙ and the corresponding time tₙ may be used to calculate the estimated change value Δi_{EX}[k] of the three-phase current during each switching cycle Tₛ:

$$Δ {i}_{EX} [ k ] = {\sum }_{n = 0}^{7} {K}_{n}^{X} {t}_{n}$$

Taking A-phase as an example, a calculation result Δi_{EA}[k] is shown in (c) of FIG. 3.

(3) A residual δi_{X}[k] of the three-phase current during each switching cycle is calculated through the above the calculation result Δi_{EX}[k] and the change value Δi_{X}[k], that is:

$$δ {i}_{X} [ k ] = Δ {i}_{X} [ k ] - Δ {i}_{EX} [ k ]$$

Taking A-phase as an example, a calculation result δi_{A}[k] is shown in (d) of FIG. 3.

(4) The residual δi_{X}[k] of the three-phase current during all the switching cycles during a previous basic cycle T₀ of a current time is accumulated to obtain an accumulated value δi_{TX}[k] of the residual of the three-phase current during the basic cycle T₀, that is:

$$δ {i}_{TX} [ k ] = δ {i}_{X} [ k - {T}_{0} / {T}_{s} + 1 ] + δ {i}_{X} [ k - {T}_{0} / {T}_{s} + 2 ] + … + δ {i}_{X} [ k - 1 ] + δ {i}_{X} [ k ]$$

The results of accumulated values δi_{TA}[k], δi_{TB}[k], and δi_{TC}[k] of the residual of the three-phase current during the basic cycle T₀ are respectively shown in (e), (f), and (g) of FIG. 3.

(5) According to a comparison between the accumulated value δi_{TX}[k] of the residual of the three-phase current during one basic cycle T₀ and a threshold Th, the power transistor that has the open-circuit fault is determined.

When the six power transistors are all normal, the estimated change value Δi_{EX}[k] of the three-phase current during each switching cycle Tₛ is basically the same as the change value Δi_{X}[k] of the three-phase current sampling signal during each switching cycle Tₛ. Therefore, the accumulated value δi_{TX}[k] of the residual of the three-phase current during the basic cycle T₀ is very small, as shown in (e), (f), and (g) of FIG. 3, before the power transistor S₁ is faulty, the accumulated value δi_{TX}[k] of the residual of the three-phase current during the basic cycle T₀ is very small. When the power transistor has the open-circuit fault, the accumulated value δi_{TX}[k] of the residual of the three-phase current during the basic cycle T₀ increases, as shown in (e), (f), and (g) of FIG. 3, after the power transistor S₁ is faulty, the accumulated value δi_{TX}[k] of the residual of the three-phase current during the basic cycle T₀ changes rapidly. Therefore, the same may be used as a judgment basis for the fault diagnosis. Due to the influence of factors such as sampling error, dead zone, and inductance error, as shown in (d) of FIG. 3, before the power transistor S₁ is faulty, an A-phase current residual δi_{A}[k] is not zero during each switching cycle Tₛ. Therefore, the accumulated value δi_{TA}[k] of a residual of an A-phase current during the basic cycle T₀ is also not zero. In order to prevent misdiagnosis, only when a maximum value of the accumulated value δi_{TX}[k] of the residual of the three-phase current during the basic cycle T₀ is greater than the set threshold Th, it is determined that a fault has occurred. The disclosure has low requirements for the setting of the threshold Th, and 80% to 200% of a rated current value may be selected as the threshold Th according to the requirements for the diagnosis speed and the reliability of the diagnosis. In the embodiment of the disclosure, 150% of the rated current (12 A) is selected as the threshold Th.

When the maximum value of the accumulated value δi_{TX}[k] of the residual of the three-phase current during the basic cycle T₀ exceeds the threshold Th, the faulty power transistor is located according to Table 2, and corresponding fault signals Fₙ (n=1, 2, 3, 4, 5, 6) of the power transistor change from 0 to 1, where F₁ represents that the power switching transistor S₁ is faulty, F₂ represents that the power switching transistor S₂ is faulty, F₃ represents that the power switching transistor S₃ is faulty, F₄ represents that the power switching transistor S₄ is faulty, F₅ represents that the power switching transistor S₅ is faulty, and F₆ represents that the power switching transistor S₆ is faulty.

TABLE 2

| Faulty | | | | |
|---|---|---|---|---|
| power | | | | |
| transistor | Phase | δi_{TA} | δi_{TB} | δi_{TC} |
| None | None | −Th < | −Th < | −Th < |
| | | δi_{TA} < Th | δi_{TB} < Th | δi_{TC} < Th |
| S₁ | A | >Th | <0 | <0 |
| S₄ | A | <−Th | >0 | >0 |
| S₃ | B | <0 | >Th | <0 |
| S₆ | B | >0 | <−Th | >0 |
| S₅ | C | <0 | <0 | >Th |
| S₂ | C | >0 | >0 | <−Th |

As shown in (e), (f), and (g) of FIG. 3, after the power transistor S₁ is faulty, the accumulated value δi_{TA}[k] rapidly exceeds the threshold Th, and at this time, the accumulated values δi_{TB}[k] and δi_{TC}[k] are both less than 0, which complies with Table 2. As shown in (h) of FIG. 3, 0.9 ms after the power transistor S₁ is faulty, F₁ rapidly changes from 0 to 1, and F₂ to F₆ remain at 0, that is, the model-based fault diagnosis algorithm of the disclosure can quickly and accurately complete the diagnosis of the open-circuit fault of the three-phase two-level power transistor.

The disclosure also provides a model-based system for diagnosing an open-circuit fault of a power transistor of a three-phase converter, which includes the following.

A diagnosis signal obtaining module is configured to obtain relevant signals for diagnosis from a control system of the converter. The relevant signals include an alternating current side three-phase current sampling signal i_{X}[k] of the converter, an alternating current side three-phase voltage sampling signal e_{X}[k], where the subscript X (=A, B, or C) represents a present phase sequence and k represents a sampling time, a direct current side voltage sampling signal U_{dc}[k], and drive signals s₁[k] to s₆[k] output by the control system.

A first calculation module is configured to calculate an estimated change value Δi_{EX}[k] of a three-phase current during each switching cycle Tₛ through the alternating current side three-phase voltage sampling signal e_{X}[k], the direct current side voltage sampling signal U_{dc}[k], and the drive signals s₁[k] to s₆[k] output by the control system according to a converter model.

A second calculation module is configured to calculate a residual δi_{X}[k] of the three-phase current during each switching cycle Tₛ according to a change value Δi_{X}[k] of a three-phase current sampling signal during each switching cycle Tₛ and the estimated change value Δi_{EX}[k] of the three-phase current.

A third calculation module is configured to calculate an accumulated value δi_{TX}[k] of a residual of the three-phase current during one basic cycle T₀ according to the residual δi_{X}[k] of the three-phase current during each switching cycle Tₛ.

A fault diagnosis module is configured to determine the power transistor that has the open-circuit fault according to a comparison between the accumulated value δi_{TX}[k] of the residual of the three-phase current during each basic cycle T₀ and a threshold Th.

For the specific implementation of each module, reference may be made to the description of the foregoing embodiment of the method, which will not be repeated in the embodiment of the disclosure.

It should be noted that according to implementation requirements, each step/component described in the disclosure may be split into more steps/components or two or more steps/components or partial operation of a step/component may be combined into a new step/component to implement the objective of the disclosure.

Persons skilled in the art may easily understand that the above are only preferred embodiments of the disclosure and are not intended to limit the disclosure. Any modification, equivalent replacement, improvement, etc., made within the spirit and principle of the disclosure should be included in the protection scope of the disclosure.

What is claimed is:

1. A model-based method for diagnosing an open-circuit fault of a power transistor of a three-phase converter, comprising:
Step (1) of obtaining relevant signals for diagnosis from a control system of the converter, wherein the relevant signals comprise an alternating current side three-phase current sampling signal i_{X}[k] of the converter, an alternating current side three-phase voltage sampling signal e_{X}[k], a direct current side voltage sampling signal U_{dc}[k], and drive signals s₁[k] to s₆[k] output by the control system, where a subscript X=A, B, or C and represents a present phase sequence, and k represents a sampling time;
Step (2) of calculating an estimated change value Δi_{EX}[k] of a three-phase current during each switching cycle Tₛ through the alternating current side three-phase voltage sampling signal e_{X}[k], the direct current side voltage sampling signal U_{dc}[k], and the drive signals s₁[k] to s₆[k] output by the control system according to a converter model;
Step (3) of calculating a residual δi_{X}[k] of the three-phase current during each switching cycle Tₛ according to a change value Δi_{X}[k] of a three-phase current sampling signal during each switching cycle Tₛ and the calculated estimated change value Δi_{EX}[k] of the three-phase current;
Step (4) of calculating an accumulated value δi_{TX}[k] of a residual of the three-phase current during a previous basic cycle T₀ of the switching cycle Tₛ according to the residual δi_{X}[k] of the three-phase current during each switching cycle Tₛ; and
Step (5) of determining the power transistor that has the open-circuit fault according to a comparison between the accumulated value δi_{TX}[k] of the residual of the three-phase current during one basic cycle T₀ and a threshold Th.

2. The method for diagnosing the open-circuit fault of the power transistor according to claim 1, wherein: in Step (2), the converter model refers to a mathematical model derived from Kirchhoff s voltage law and Kirchhoff s current law in combination with a topology of the converter.

3. The method for diagnosing the open-circuit fault of the power transistor according to claim 2, wherein: in Step (2), the switching cycle Tₛ is a reciprocal of a switching frequency fₛ, and the estimated change value Δi_{EX}[k] of the three-phase current during each switching cycle Tₛ is implemented through a state observer and a mixed logic dynamic model according to the converter model.

4. The method for diagnosing the open-circuit fault of the power transistor according to claim 1, wherein: in Step (3), the change value Δi_{X}[k] of the three-phase current sampling signal during each switching cycle Tₛ calculated from Δi_{X}[k]=i_{X}[k]−i_{X}[k−1] refers to a difference between three-phase current sampling signal i_{X}[k] corresponding to a start and an end of each switching cycle Tₛ.

5. The method for diagnosing the open-circuit fault of the power transistor according to claim 4, wherein: in Step (4), the basic cycle T₀ refers to a reciprocal of a three-phase voltage frequency f₀, and the accumulated value δi_{TX}[k] of the residual of the three-phase current during the basic cycle T₀ calculated from δi_{TX}[k]=δi_{X}[k−T₀/Tₛ+1]+δi_{X}[k−T₀/Tₛ+2]+ . . . +δi_{X}[k−1]+δi_{X}[k] refers to a sum of the residual δi_{X}[k] of the three-phase current during all the switching cycles during the previous basic cycle T₀ of a current time.

6. The method for diagnosing the open-circuit fault of the power transistor according to claim 5, wherein: in Step (5), the threshold Th refers to a threshold value set to prevent misdiagnosis, after the accumulated value δi_{TX}[k] of the residual of the three-phase current during the basic cycle T₀ exceeds the threshold Th, it is determined that the power transistor has the open-circuit fault.

7. The method for diagnosing the open-circuit fault of the power transistor according to claim 6, wherein: in Step (5), for different faults of the power transistor, the accumulated value δi_{TX}[k] of the residual of the three-phase current during the basic cycle T₀ is different, so that a faulty power transistor can be located through the accumulated value δi_{TX}[k].

8. The method for diagnosing the open-circuit fault of the power transistor according to claim 7, wherein: in Step (5), when a maximum value of the accumulated value δi_{TX}[k] of the residual of the three-phase current during the basic cycle T₀ is greater than the set threshold Th, it is determined that a fault has occurred.

9. A model-based system for diagnosing an open-circuit fault of a power transistor of a three-phase converter, comprising:
a diagnosis signal obtaining module, configured to obtain relevant signals for diagnosis from a control system of the converter, wherein the relevant signals comprise an alternating current side three-phase current sampling signal i_{X}[k] of the converter, an alternating current side three-phase voltage sampling signal e_{X}[k], a direct current side voltage sampling signal U_{dc}[k], and drive signals s₁[k] to s₆[k] output by the control system, where a subscript X (=A, B, or C) represents a present phase sequence and k represents a sampling time;
a first calculation module, configured to calculate an estimated change value Δi_{EX}[k] of a three-phase current during each switching cycle Tₛ through the alternating current side three-phase voltage sampling signal e_{X}[k], the direct current side voltage sampling signal U_{dc}[k], and the drive signals s₁[k] to s₆[k] output by the control system according to a converter model;
a second calculation module, configured to calculate a residual δi_{X}[k] of the three-phase current during each switching cycle Tₛ according to a change value Δi_{X}[k] of a three-phase current sampling signal during each switching cycle Tₛ and the estimated change value Δi_{EX}[k] of the three-phase current;
a third calculation module, configured to calculate an accumulated value δi_{TX}[k] of a residual of the three-phase current during one basic cycle T₀ according to the residual δi_{X}[k] of the three-phase current during each switching cycle Tₛ; and
a fault diagnosis module, configured to determine the power transistor that has the open-circuit fault according to a comparison between the accumulated value δi_{TX}[k] of the residual of the three-phase current during each basic cycle T₀ and a threshold Th.

10. A computer-readable storage medium stored with a computer program, characterized in that when the computer program is executed by a processor, steps of the method according to claim 1 are implemented.

11. The method for diagnosing the open-circuit fault of the power transistor according to claim 2, wherein: in Step (3), the change value Δi_{X}[k] of the three-phase current sampling signal during each switching cycle Tₛ calculated from Δi_{X}[k]=i_{X}[k]−i_{X}[k−1] refers to a difference between three-phase current sampling signal i_{X}[k] corresponding to a start and an end of each switching cycle Tₛ.

12. The method for diagnosing the open-circuit fault of the power transistor according to claim 11, wherein: in Step (4), the basic cycle T₀ refers to a reciprocal of a three-phase voltage frequency f₀, and the accumulated value δi_{TX}[k] of the residual of the three-phase current during the basic cycle T₀ calculated from δi_{TX}[k]=δi_{X}[k−T₀/Tₛ+1]+δi_{X}[k−T₀/Tₛ+2]+ . . . +δi_{X}[k−1]+δi_{X}[k] refers to a sum of the residual δi_{X}[k] of the three-phase current during all the switching cycles during the previous basic cycle T₀ of a current time.

13. The method for diagnosing the open-circuit fault of the power transistor according to claim 12, wherein: in Step (5), the threshold Th refers to a threshold value set to prevent misdiagnosis, after the accumulated value δi_{TX}[k] of the residual of the three-phase current during the basic cycle T₀ exceeds the threshold Th, it is determined that the power transistor has the open-circuit fault.

14. The method for diagnosing the open-circuit fault of the power transistor according to claim 13, wherein: in Step (5), for different faults of the power transistor, the accumulated value δi_{TX}[k] of the residual of the three-phase current during the basic cycle T₀ is different, so that a faulty power transistor can be located through the accumulated value δi_{TX}[k].

15. The method for diagnosing the open-circuit fault of the power transistor according to claim 14, wherein: in Step (5), when a maximum value of the accumulated value δi_{TX}[k] of the residual of the three-phase current during the basic cycle T₀ is greater than the set threshold Th, it is determined that a fault has occurred.

16. The method for diagnosing the open-circuit fault of the power transistor according to claim 3, wherein: in Step (3), the change value Δi_{X}[k] of the three-phase current sampling signal during each switching cycle Tₛ calculated from Δi_{X}[k]=i_{X}[k]−i_{X}[k−1] refers to a difference between three-phase current sampling signal i_{X}[k] corresponding to a start and an end of each switching cycle Tₛ.

17. The method for diagnosing the open-circuit fault of the power transistor according to claim 16, wherein: in Step (4), the basic cycle T₀ refers to a reciprocal of a three-phase voltage frequency f₀, and the accumulated value δi_{TX}[k] of the residual of the three-phase current during the basic cycle T₀ calculated from δi_{TX}[k]=δi_{X}[k−T₀/Tₛ+1]+δi_{X}[k−T₀/Tₛ+2]+ . . . +δi_{X}[k−1]+δi_{X}[k] refers to a sum of the residual δi_{X}[k] of the three-phase current during all the switching cycles during the previous basic cycle T₀ of a current time.

18. The method for diagnosing the open-circuit fault of the power transistor according to claim 17, wherein: in Step (5), the threshold Th refers to a threshold value set to prevent misdiagnosis, after the accumulated value δi_{TX}[k] of the residual of the three-phase current during the basic cycle T₀ exceeds the threshold Th, it is determined that the power transistor has the open-circuit fault.

19. The method for diagnosing the open-circuit fault of the power transistor according to claim 18, wherein: in Step (5), for different faults of the power transistor, the accumulated value δi_{TX}[k] of the residual of the three-phase current during the basic cycle T₀ is different, so that a faulty power transistor can be located through the accumulated value δi_{TX}[k].

20. The method for diagnosing the open-circuit fault of the power transistor according to claim 19, wherein: in Step (5), when a maximum value of the accumulated value δi_{TX}[k] of the residual of the three-phase current during the basic cycle T₀ is greater than the set threshold Th, it is determined that a fault has occurred.
